(19) United States
(12) Patent Application Publication
(10) Pub. No.: US 2024/0347556 A1
(43) Pub. Date: Oct. 17, 2024

(54) SEMICONDUCTOR APPARATUS AND EQUIPMENT

(71) Applicant: CANON KABUSHIKI KAISHA, Tokyo (JP)

(72) Inventors: HIDEO KOBAYASHI, Tokyo (JP); YUJI NAKAJIMA, Tokyo (JP); KAZUHIRO SAITO, Tokyo (JP)

(21) Appl. No.: 18/626,184

(22) Filed: Apr. 3, 2024

(30) Foreign Application Priority Data
Apr. 14, 2023 (JP) 2023-066474

(51) Int. Cl. H01L 27/146

(52) U.S. Cl. CPC H01L 27/14603; H01L 27/14612; H01L 27/14627; H01L 27/14636

(57) ABSTRACT

A semiconductor apparatus includes a structure and a wiring portion. The structure includes a pixel array having a plurality of pixels arranged in a plurality of rows and a plurality of columns, a circuit unit that scans the plurality of pixels or processes signals output from the plurality of pixels, and a voltage generation circuit that generates a first voltage. The wiring portion is provided outside of the structure. The first voltage is supplied from the voltage generation circuit to the circuit unit via the wiring portion.

### BACKGROUND

### Field

The present disclosure relates to a semiconductor apparatus and equipment.

### Description of the Related Art

Semiconductor apparatuses in which functional elements are provided in a semiconductor element layer have been developed. As an example of the semiconductor apparatus, an image pickup device including a drive unit that selects a pixel row from which signals are read out and a power supply unit that supplies a voltage to the drive unit is described in Japanese Patent Laid-Open No. 2022-23639. The drive unit is supplied with a voltage via a conductor line from the power supply unit provided inside the image pickup device.

### SUMMARY

According to an aspect of the present disclosure, a semiconductor apparatus includes a structure including a pixel array having a plurality of pixels arranged in a plurality of rows and a plurality of columns, a circuit unit configured to scan the plurality of pixels or process signals output from the plurality of pixels, and a voltage generation circuit configured to generate a first voltage, and a wiring portion provided outside of the structure, wherein the first voltage is supplied from the voltage generation circuit to the circuit unit via the wiring portion.

Further features of the present disclosure will become apparent from the following description of exemplary embodiments with reference to the attached drawings.

### BRIEF DESCRIPTION OF THE DRAWINGS

FIG. 1 is a schematic illustration of an image pickup device according to a first embodiment.

FIG. 2 is a schematic illustration of the image pickup device according to the first embodiment.

FIG. 3 is a schematic illustration of the image pickup device according to the first embodiment.

FIG. 4 is a schematic illustration of the image pickup device according to the first embodiment.

FIG. 5 is a schematic illustration of the image pickup device according to the first embodiment.

FIGS. 6A and 6B are schematic illustrations of the image pickup device according to the first embodiment.

FIG. 7 illustrates a comparative example of the image pickup device for describing the effects of the first embodiment.

FIG. 8 illustrates a comparative example of the image pickup device for describing the effects of the first embodiment.

FIG. 9 is a schematic illustration of the image pickup device according to the first embodiment.

FIG. 10 is a schematic illustration of the image pickup device according to the first embodiment.

FIG. 11 is a schematic illustration of an image pickup device according to a second embodiment.

FIG. 12 illustrates a comparative example of the image pickup device for describing the effects of the second embodiment.

FIG. 13 illustrates a comparative example of the image pickup device for describing the effects of the second embodiment.

FIG. 14 illustrates a comparative example of the image pickup device for describing the effects of the second embodiment.

FIG. 15 is a schematic illustration of an image pickup device according to a third embodiment.

FIG. 16 is a schematic illustration of an image pickup device according to a fourth embodiment.

FIG. 17 is a schematic illustration of the image pickup device according to the fourth embodiment.

FIGS. 18A to 18C are schematic illustrations of equipment according to a fifth embodiment.

### DESCRIPTION OF THE EMBODIMENTS

Embodiments of the present disclosure are described below with reference to the accompanying drawings. In the description and drawings below, the same reference numerals are used for configurations that are the same or similar throughout a plurality of drawings. For this reason, description of the configurations having the same reference numerals is omitted as appropriate.

The embodiments below are described with reference to solid-state image pickup devices as examples of semiconductor apparatuses. However, the embodiments are not limited to the solid-state image pickup devices and can be applied to other examples of semiconductor apparatuses. For example, the embodiments can be applied to distance measurement devices, such as devices for detecting a focal point, devices for measuring a distance using Time of Flight (TOF), and light metering devices (devices for measuring the quantity of incident light).

Metal members, such as a conductor line and a pad portion, described herein may be composed of a single element metal or may be a mixed metal (alloy). For example, a conductor line described as a copper conductor line may be composed of a single element of copper or may be composed primarily of copper with additional another component.

For example, a pad that is connected to an external terminal may be composed of a single element of aluminum or may be composed primarily of aluminum with additional another component.

The copper conductor line and aluminum pad described herein are only examples and can be changed to various metal wiring.

The conductor line and pad portion described herein are examples of metal members used in a semiconductor apparatus and are applicable to other metal members.

In the embodiments below, connection between circuit elements may be described. In this case, even if a certain element is disposed between the elements of interest, the elements of interest are treated as connected to each other unless otherwise specified. For example, suppose that an element A is connected to one node of a capacitor element C having multiple nodes while an element B is connected to the other node. Even in such a case, the element A and the element B are treated as connected, unless otherwise specified.

### First Embodiment

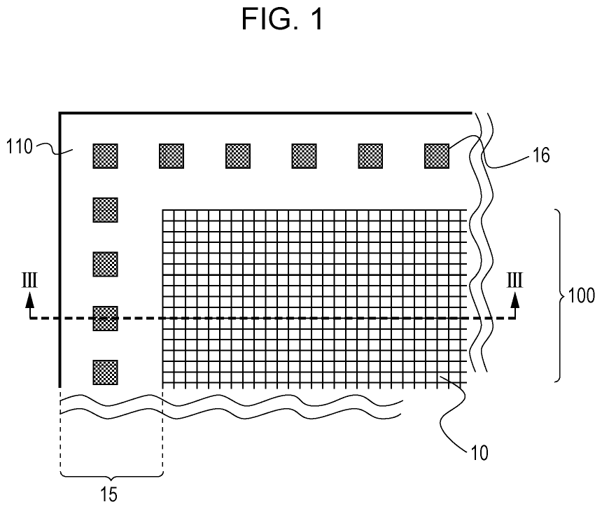

FIGS. 1 to 5 and FIGS. 6A and 6B are schematic illustrations of a solid-state image pickup device according to the first embodiment. A solid-state image pickup device 1000 according to the present embodiment has a layered structure in which a pixel substrate 110 and a circuit substrate 150 are joined together.

FIG. 1 is a schematic illustration of the pixel substrate 110 that constitutes a solid-state image pickup device, viewed from the upper surface of the image pickup device (in the normal direction of a light receiving surface of the solid-state image pickup device). The pixel substrate 110 includes a pixel array 100 having a plurality of pixels 10 arranged in a plurality of rows and a plurality of columns. In addition, a plurality of pad portions 16 are arranged in an outer periphery region 15.

The plurality of pad portions 16 energize the solid-state image pickup device, a signal processing device, and the like disposed outside the solid-state image pickup device. The plurality of pad portions 16 include pad portions that output signals from the solid-state image pickup device to the outside and pad portions that input the power supply voltage and the like to the solid-state image pickup device.

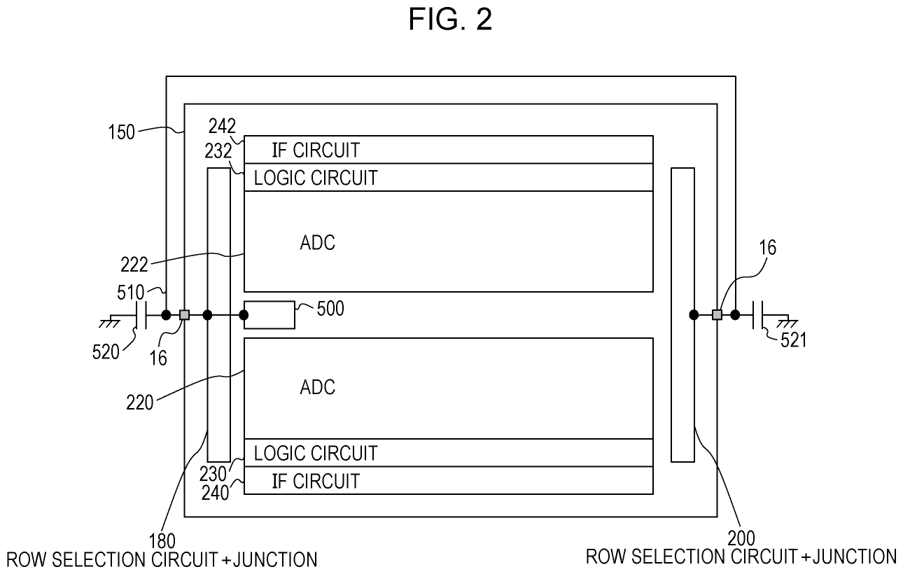

FIG. 2 is a schematic illustration of the circuit substrate 150 viewed from the upper surface of the solid-state image pickup device (in the direction normal to the light receiving surface of the image pickup device). The circuit substrate 150 includes a row selection circuit 180 and a row selection circuit 200. The row selection circuit 180 and the row selection circuit 200 supply a row selection signal to each of rows of the pixel array 100 via a junction that electrically connect the pixel substrate 110 with the circuit substrate 150. A plurality of pixels 10 included in a pixel row to which the row selection signal is input output signals each having a signal level corresponding to the quantity of incident light to signal lines 30 (described below).

The circuit substrate 150 includes an analog-to-digital (AD) converter (ADC) 220 and an ADC 222 that process the signals from the pixels 10. The circuit substrate 150 further includes a logic circuit 230 and a logic circuit 232 that process the signals from the ADC 220 and ADC 222, respectively.

The circuit substrate 150 further includes an interface (IF) circuit 240 and an IF circuit 242 that output signals from the logic circuit 230 and logic circuit 232 to the outside, respectively. The circuit substrate 150 further includes a voltage generation circuit 500. A wiring portion 510, a capacitor element 520, and a capacitor element 521 are provided outside of the circuit substrate 150.

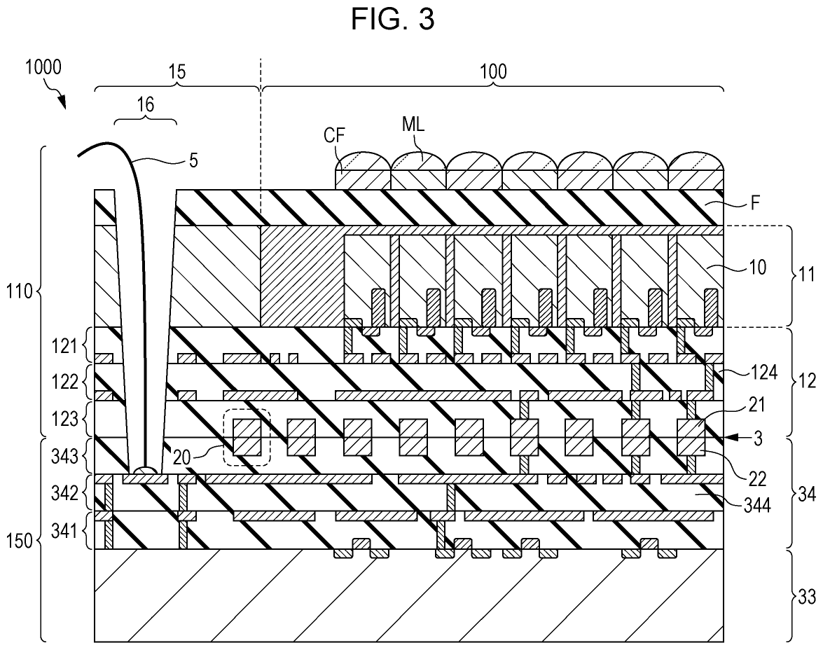

FIG. 3 is a cross-sectional view taken along line III-III of FIG. 1. In FIG. 3, the pixel substrate 110 and the circuit substrate 150 are joined at a joint surface 3. A trench that serves as the pad portion 16 is formed at an end portion of a semiconductor element layer 11. The trench is formed from the light incident surface of the semiconductor element layer 11 to extend in a depth direction to a depth until a wiring pattern of a wiring layer 342 of the circuit substrate 150 is reached.

In the pad portion 16, a bonding wire 5 allows the wiring layer 342 formed in the circuit substrate 150 to electrically coupled to the outside of an image pickup element. For example, a gold-based material is suitably used as the material of the bonding wire.

A wiring structure 12 of the pixel substrate 110 and a wiring structure 34 of the circuit substrate 150 are located between the semiconductor element layer 11 of the pixel substrate 110 and a semiconductor element layer 23 of the circuit substrate 150. As illustrated in FIG. 3, the wiring structure 12 includes three wiring layers 121, 122, and 123, and the wiring structure 34 includes three wiring layers 341, 342, and 343.

The wiring structure 12 includes three wiring layers 121, 122, and 123. The wiring layers 121, 122, and 123 can be, for example, Cu wiring layers. In FIG. 3, the wiring layer 123 constitutes a metal portion 21 of a metal junction 20. The metal junction 20 is embedded in a recess formed in an interlayer insulating film and has a damascene structure.

The wiring structure 34 has three wiring layers 341, 342, and 343. The wiring layers 341, 342, and 343 can be Cu wiring layers. In FIG. 3, the wiring layer 343 constitutes a metal portion 22 of the metal junction 20. The metal portion 22 is embedded in a recess formed in the interlayer insulating film and has a damascene structure.

The interlayer insulating film with the recess in which the metal portion 21 is embedded and the interlayer insulating film with the recess in which the metal portion 22 is embedded are joined (in contact with each other) by the metal portion 21 and the metal portion 22. The metal portion 21 and the metal portion 22 are joined to form the metal junction 20.

A via plug 124 formed in the interlayer insulating film of the wiring layer 123 enables the metal portion 21 to be electrically coupled to the wiring layer 122. The via plug 344 formed in the interlayer insulating film of the wiring layer 343 enables the metal portion 22 to be electrically coupled with the wiring layer 342. The metal junction 20 in which the via plugs 124 and 344 are joined causes the semiconductor element layer 11 and the semiconductor element layer 23 to be electrically connected to each other.

For example, in FIG. 3, the wiring pattern of the wiring layer 123 is electrically connected to the wiring pattern of the wiring layer 122, which is the upper layer of the wiring layer 123, via the via plug 124. The wiring pattern of the wiring layer 343 is electrically connected to the wiring pattern of the wiring layer 342, which is the lower layer of the wiring layer 343, via the via plug 344. The via plugs are not essential. A wiring pattern may be in direct contact with a wiring pattern in the upper or lower layer for electrical connection.

In FIG. 3, the wiring patterns of the wiring layer 123 and the wiring layer 343 electrically connect the semiconductor element layer 11 to the semiconductor element layer 33. It is not necessary that all wiring patterns of each of the wiring layer 123 and the wiring layer 343 electrically connect the semiconductor element layer 11 to the semiconductor element layer 33. Some of the wiring patterns may be electrically connected to the semiconductor element layer 11 or the semiconductor element layer 33. Alternatively, some wiring patterns may be electrically connected to any of the wiring layers and be electrically connected to neither the semiconductor element layer 11 nor the semiconductor element layer 33.

A microlens ML is disposed on the light incident surface of the semiconductor element layer 11 via an insulating material F. In addition, a color filter CF is disposed between the microlens ML and the insulating material F. The arrangement of the color filters CF can be selected as appropriate. For example, the arrangement may be the Bayer arrangement. In addition, a plurality of photoelectric conversion portions may be arranged for one microlens ML.

As described above, the present embodiment provides a stacked solid-state image pickup device including the pixel substrate 110 and the circuit substrate 150. A row of the pixel array 100 is selected by the row selection circuit 180 and the row selection circuit 200, and signals from the selected row are read out by the ADC 220 and ADC 222 of the circuit substrate 150 via the metal junctions 20.

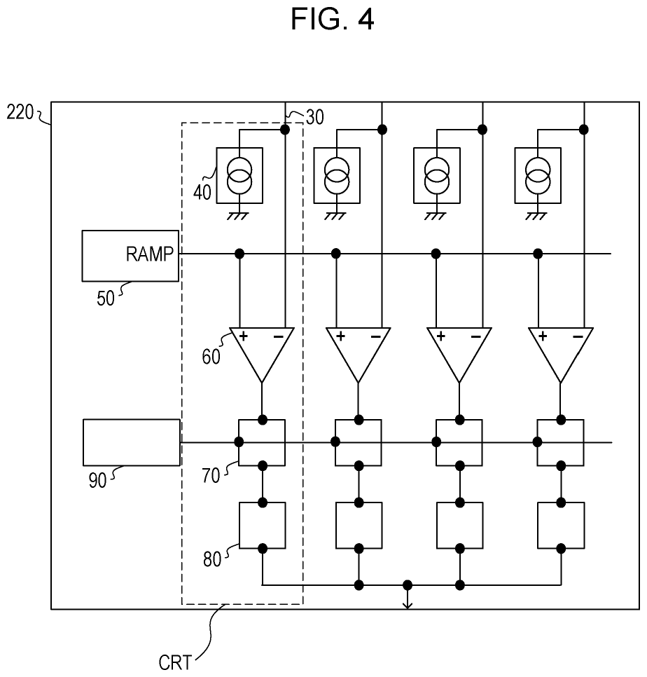

FIG. 4 is a schematic illustration of an example configuration of the ADC 220. The ADC 220 includes the signal line 30, a current source 40, a ramp signal generation circuit 50, a comparator 60, a first memory 70, a second memory 80, and a counter 90. One circuit CRT includes the current source 40, the comparator 60, the first memory 70, the second memory 80, and the counter 90. One circuit CRT is provided corresponding to one signal line 30. However, the present embodiment is not limited thereto, and one circuit CRT may be provided for a plurality of signal lines 30, or a plurality of circuits CRT may be provided for one signal line 30.

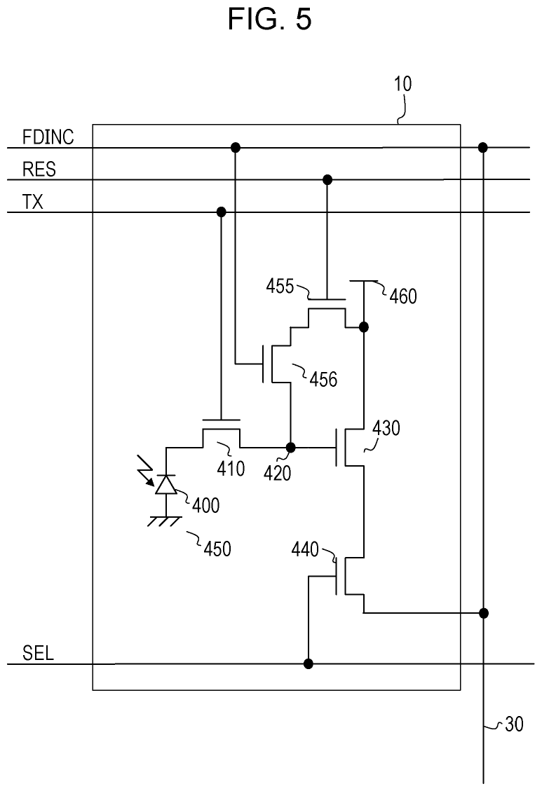

FIG. 5 is a schematic illustration of an example configuration of the pixel 10. The signal line 30 of the ADC 220 illustrated in FIG. 4 is electrically connected to the signal line 30 of the pixel illustrated in FIG. 5 by the metal junction 20 illustrated in FIG. 3. Each of the pixels of the pixel array 100 includes a photodiode 400, a transfer transistor 410, a floating diffusion 420, a source follower transistor 430, and a selection transistor 440. The pixel 10 includes a GND (ground potential) node 450, a reset transistor 455, a gain switching transistor 456, and a power supply node 460.

In FIG. 5, the photocarriers generated by the photodiode 400 are transferred to the floating diffusion 420 by switching on the transfer transistor 410 and are converted into a signal voltage by the parasitic capacitance accompanied with the floating diffusion 420. In FIG. 5, the conversion gain can be switched by switching the gain switching transistor 456 between the ON state to the OFF state.

The converted signal voltage is output to the signal line 30 via the source follower transistor 430 and the selection transistor 440. The source follower transistor 430 constitutes a source follower together with the current source 40 illustrated in FIG. 4, and the signal voltage on floating diffusion 420 is buffered by the source follower and appears on the signal line 30.

The comparator 60 compares the signal of the signal line 30 with a ramp signal output from the ramp generation circuit 50. When the comparator 60 inverts, the first memory 70 receives a count signal of the counter 90. This causes the signal of the pixel 10 to be AD converted. The digital signal in the first memory 70 is transferred to the second memory 80 and then is output to the outside of the circuit substrate 150 via the logic circuit 230, the logic circuit 232, the IF circuit 240, and the IF circuit 242 illustrated in FIG. 2.

While the present embodiment is described with reference to an example in which the counter 90 that is common to a plurality of circuits is used, a common count clock may be supplied, and a counter may be provided for each of the circuits corresponding to one of the signal lines. Even in such a configuration, the technique of the present disclosure can be applied.

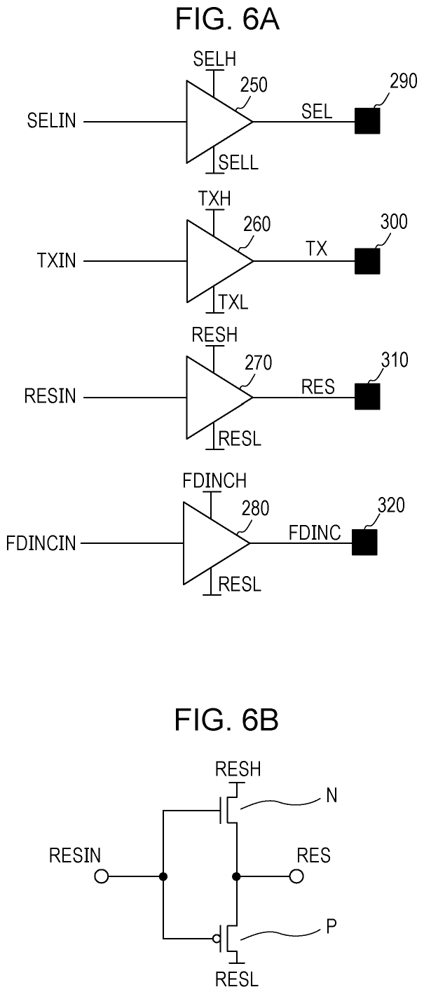

Supply of the row selection signals from the row selection circuit 180 and the row selection circuit 200 to the pixel array 100 is described below. FIGS. 6A and 6B are schematic illustrations of an inter-substrate junction between the output circuits of the row selection circuits and the pixel substrate.

FIG. 6A illustrates a drive circuit 250 that outputs a pixel selection signal SEL, a drive circuit 260 that outputs a pixel transfer signal TX, a drive circuit 270 that outputs a pixel reset signal RES, and a drive circuit 280 that outputs a pixel gain switching signal FDINC, which are provided corresponding to ten pixels in a row.

The outputs are supplied to the pixels 10 in a certain row of the pixel array 100 via the inter-substrate junctions 290, 300, 310, and 320. The configuration illustrated in FIG. 6A is provided for the pixels 10 in one row, and the configuration is repeatedly disposed for the number of pixel rows in each of the row selection circuits 180 and 200.

FIG. 6B illustrates the configuration of the drive circuit 270. The drive circuit 270 includes an N-type MOS transistor N and a P-type MOS transistor P. One of the source and drain of the N-type MOS transistor N is supplied with a voltage RESH that is the power supply voltage, and the other is connected to one of the source and drain of the P-type MOS transistor P and an output node of the drive circuit 270.

Another power supply voltage RESL is supplied to the other of the source and drain of the P-type MOS transistor P. A signal RESIN is input to the gate of each of the N-type MOS transistor N and the P-type MOS transistor P. When the signal RESIN is at a high level, a high level signal with a signal level corresponding to the voltage value obtained by subtracting a threshold voltage of the N-type MOS transistor N from the voltage RESH is output as the pixel reset signal RES.

When the signal RESIN is at a low level, a low level signal with a signal level corresponding to the voltage value obtained by subtracting a threshold voltage of the P-type MOS transistor P from the voltage RESL is output as the pixel reset signal RES. The other drive circuits 250, 260, and 280 have the same circuit configuration as the drive circuit 270, in which an N-type MOS transistor and a P-type MOS transistor are connected in series.

The output of the voltage generation circuit 500 illustrated in FIG. 2 is electrically connected to the row selection circuit 180 and the row selection circuit 200 and, as an example, is electrically connected to RESL illustrated in FIGS. 6A and 6B. In this case, each of the plurality of functional elements to which the voltage RESL, that is, the first voltage, is supplied is each of the plurality of drive circuits 270 and 280. That is, the output of the voltage generation circuit 500 is the voltage corresponding to the low level of each of the pixel reset signal RES and the pixel gain switching signal FDINC illustrated in FIG. 5.

That is, the output of the voltage generation circuit 500 is used to generate signals to be input to the reset transistor and the gain switching transistor of the pixel 10. By providing the voltage generation circuit 500 inside the circuit substrate 150 in this manner, the number of voltage supply parts provided outside of the circuit substrate can be reduced.

The low level of each of the signals output to the pixel 10 by the row selection circuits 180 and 200 may be a negative voltage. The negative voltage can be generated by the voltage generation circuit 500 provided inside of the solid-state image pickup device 1000. More specifically, the voltage RESL is a negative voltage in the range of −0.1 V to −1 V. The voltage generation circuit 500 generates the voltage RESL. The voltage RESL is supplied to the row selection circuits 180 and 200 via the wiring portion 510 outside of the solid-state image pickup device 1000. This enables the voltage RESL to be supplied with small voltage fluctuation.

The voltage generation circuit 500 may be a circuit that generates only negative voltages. In this case, the positive voltages RESH, SELH, TXH, and FDINCH may be supplied from a voltage generation circuit provided outside of the solid-state image pickup device 1000.

In FIG. 2, the voltage generation circuit 500 and the row selection circuit 200 are electrically connected using the wiring portion 510 outside of the solid-state image pickup device 1000. In general, the thickness of the wiring layer in the circuit substrate 150 is 0.1 μm to several μm. However, because the thickness of inner layer wiring of a package containing the solid-state image pickup device 1000 is several hundred μm, the wiring outside of the solid-state image pickup device 1000 has a sheet resistance that is more than two orders of magnitude lower. The connection illustrated in FIG. 2 reduces the impedance from the voltage generation circuit 500 to the row selection circuit 200 and, thus, degradation of image quality caused by the voltage fluctuation of the wiring that supplies the power supply voltage (the first voltage) can be prevented.

FIG. 7 illustrates a comparative example. In FIG. 7, a second voltage generation circuit 501 is provided to supply a voltage to the row selection circuit 200. In this case, due to characteristic variations of the voltage generation circuit 500 and the second voltage generation circuit 501, the voltages supplied to the row selection circuits 180 and 200 do not completely the same. As a result, the voltages supplied to the pixels from the right and from the left are not the same, which causes shading to occur.

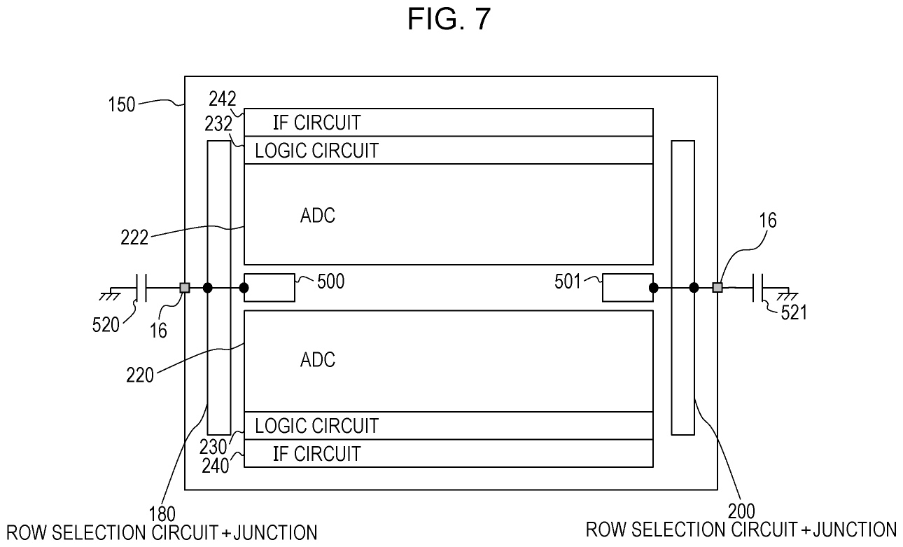

FIG. 8 illustrates another comparative example. In FIG. 8, a voltage is supplied from the voltage generation circuit 500 to the row selection circuit 200 by only the wiring portion inside of the solid-state image pickup device 1000 without using the wiring portion 510 outside of the solid-state image pickup device 1000. In this case, the long distance between the voltage generation circuit 500 and the row selection circuit 200 increases the parasitic resistance of the conductor line that supplies the voltage and, thus, degradation of image quality caused by voltage fluctuations may occur.

According to the present embodiment, by supplying a voltage from the same voltage generation circuit 500 to the row selection circuits 180 and 200 and supplying the voltage to at least one of the row selection circuits 180 and 200 via a conductor line outside of the solid-state image pickup device 1000, degradation of image quality caused by voltage fluctuations can be prevented. In addition, the capacitor elements 520 and 521 provided outside of the solid-state image pickup device 1000 are connected to the conductor line outside of the solid-state image pickup device 1000. In this way, the voltage fluctuation of the wiring portion 510 can be further prevented, and degradation of image quality can be prevented.

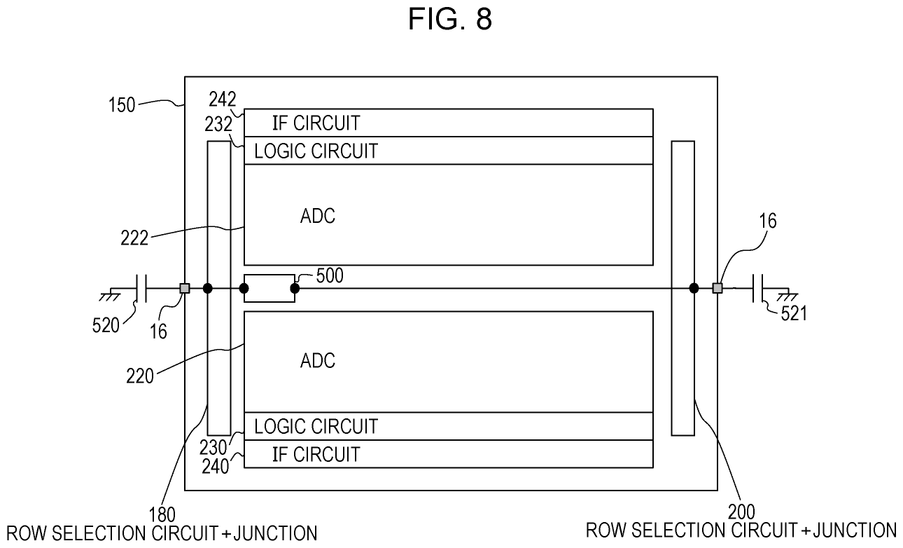

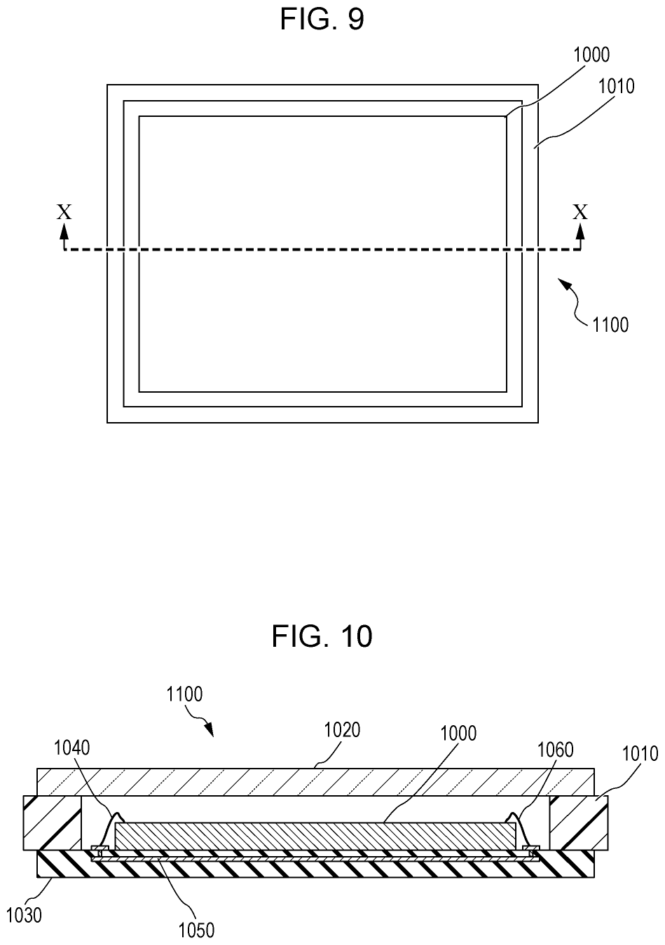

FIG. 9 is a schematic illustration of an image pickup module including the solid-state image sensor according to the present embodiment, viewed from the upper surface (in the normal direction of the light receiving surface of the solid-state image pickup device). In FIG. 9, the solid-state image pickup device 1000 includes the pixel substrate 110 and the circuit substrate 150, and a resin frame 1010 is provided in the outer peripheral portion of the solid-state image pickup device 1000.

FIG. 10 is a cross-sectional view taken along line X-X of FIG. 9. As illustrated in FIG. 10, an image pickup module 1100 includes a transparent member 1020 and a printed substrate 1030. The transparent member 1020 is fixed to the printed substrate 1030 via the resin frame 1010. The image pickup module 1100 further includes bonding wires 1040 and 1060 and inner layer wiring 1050 as the inner layer wiring of the printed substrate 1030.

In FIG. 2, the voltage output from the voltage generation circuit 500 is supplied again to the solid-state image pickup device 1000 via the bonding wire 1040, the inner layer wiring 1050, and the bonding wire 1060 illustrated in FIG. 10 and is supplied to the row selection circuit 200 illustrated in FIG. 2. The wiring portion 510 outside of the solid-state image pickup device 1000 illustrated in FIG. 2 corresponds to the inner layer wiring 1050 illustrated in FIG. 10. The bonding wires 5 illustrated in FIG. 3 correspond to the bonding wires 1040 and 1060 illustrated in FIG. 10.

While the example in which the inner layer wiring is used has been described with reference to FIG. 10, surface layer wiring of the printed substrate 1030 may be used. In the example illustrated in FIG. 10, the inner layer wiring 1050 and the solid-state image pickup device 1000 are arranged so as to have an overlapping portion in plan view as seen from the upper surface of the image pickup module 1100, but the arrangement is not limited thereto.

However, the wiring path can be reduced by arranging the inner layer wiring 1050 to have an overlapping portion of the solid-state image pickup device 1000 and the image pickup module 1100 in plan view as seen from the upper surface. This can reduce the impedance of the conductor line that supplies a voltage. When the semiconductor apparatus is a solid-state image pickup device, this is advantageous for preventing the degradation of image quality. Even if the semiconductor apparatus is a semiconductor apparatus other than a solid-state image pickup device, it is possible to prevent a decrease in operating precision of functional elements to which voltage is supplied via a wiring portion outside of the semiconductor apparatus.

The voltage generation circuit 500 may be provided on the pixel substrate 110. In this case, it is desirable to place the voltage generation circuit 500 and the row selection circuits 180 and 200 on the same substrate. That is, if the row selection circuits 180 and 200 are provided on the pixel substrate 110, the voltage generation circuit 500 also be provided on the pixel substrate 110. Alternatively, if the row selection circuits 180 and 200 are provided on the circuit substrate 150, the voltage generation circuit 500 is also provided on the circuit substrate 150. In this way, electrical connection between the voltage generation circuit 500 and each of the row selection circuit 180 and the row selection circuit 200 can be made without using an inter-substrate junction.

In particular, it is desirable to place the voltage generation circuit 500 on the circuit substrate 150, as illustrated in FIG. 2. This can simplify the manufacturing process of the pixel substrate 110. Heat resulting from the operating power of the voltage generation circuit 500 may be transferred to the pixel array 100, causing shading in the image due to uneven heat. By placing the voltage generation circuit 500 on the circuit substrate 150, the shading caused by heat can be prevented.

While the present embodiment has been described with reference to the example in which a layered structure including the stacked pixel substrate 110 and circuit substrate 150 is used as an example of a structure including a pixel array and a circuit unit, the present embodiment is not limited thereto. The solid-state image pickup device 1000 may have a non-layered structure in which the pixel array 100 illustrated in FIG. 1 and the functional blocks illustrated in FIG. 2 are provided on a single substrate.

### Second Embodiment

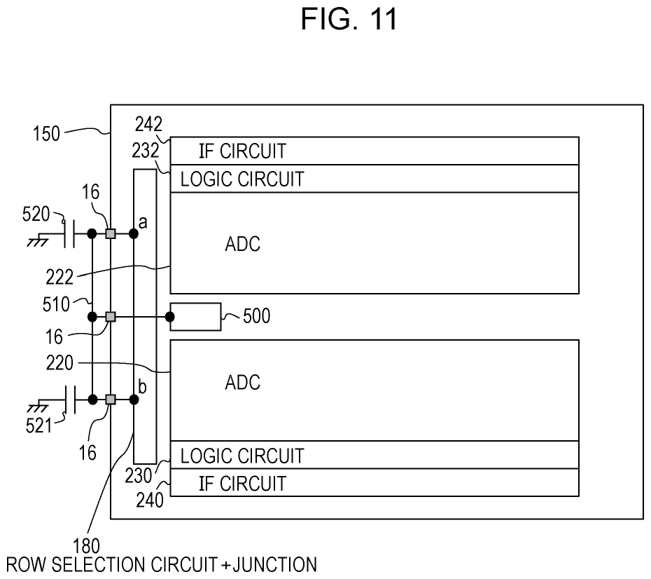

FIG. 11 is a schematic illustration of a solid-state image pickup device according to the present embodiment. Only the differences from FIG. 2 according to the first embodiment are described below.

According to the present embodiment, only the row selection circuit 180 is provided. The voltage is supplied from the voltage generation circuit 500 to the row selection circuit 180 at two connection points a and b. By supplying the voltage from two locations, the degradation of image quality caused by the impedance of the wiring inside of the row selection circuit 180 can be prevented.

Each of the connection points a and b is a portion of each of the wiring layers illustrated in FIG. 3 that connects with the wiring layer located relatively lower or that contacts with a semiconductor layer of the circuit substrate 150. Each of the connection points a and b may include a plurality of points of contact in one connection point. In this case, the wiring layers are connected to each other using a plurality of vias as the points of contact.

It is desirable that the connection points a and b be provided near each of both ends of each of the row selection circuits 180 and that conductor lines be provided so as to extend from both the ends (the connection points a and b) toward the center of the row selection circuit 180.

By supplying voltage to the connection points a and b via the wiring portion 510 outside of the solid-state image pickup device 1000, the impedance of the supply path can be reduced and, thus, degradation of image quality can be further reduced. Therefore, it is desirable that at least one of connection points a and b supply voltage via a conductor line outside of the solid-state image pickup device 1000.

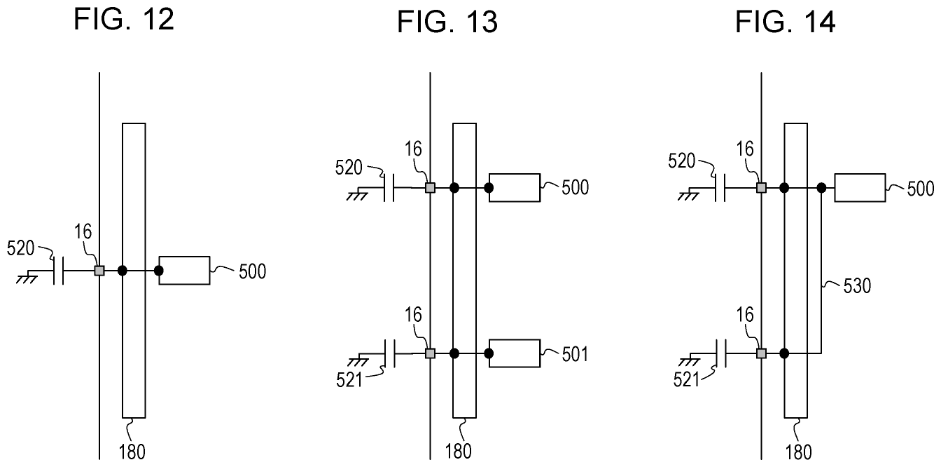

FIGS. 12 to 14 illustrate comparative examples. In FIG. 12, voltage is supplied from the voltage generation circuit 500 to the row selection circuit 180 at only one location. In this case, degradation of image quality caused by the impedance of the conductor line inside of the row selection circuit 180 is likely to occur.

In the comparative example illustrated in FIG. 13, voltage is supplied from two voltage generation circuits 500 and 501. In this case, the supplied voltages may be different due to variations in the characteristics of the voltage generation circuits 500 and 501. As a result, potential shading occurs in the vertical direction in the row selection circuit 180, which is another cause of degradation of image quality.

Like FIG. 11, in the comparative example illustrated in FIG. 14, voltage is supplied from a single voltage generation circuit 500 to the row selection circuit 180 at two locations. However, the voltage is supplied via a conductor line 530 inside of the solid-state image pickup device 1000, which may cause degradation of image quality due to parasitic resistance of the conductor line 530 inside of the solid-state image pickup device 1000.

As described above, by supplying voltage from a single voltage generation circuit 500 to two locations of the row selection circuit 180 and supplying the voltage at least one of the two locations via a conductor line outside of the solid-state image pickup device 1000, degradation of image quality can be reduced.

### Third Embodiment

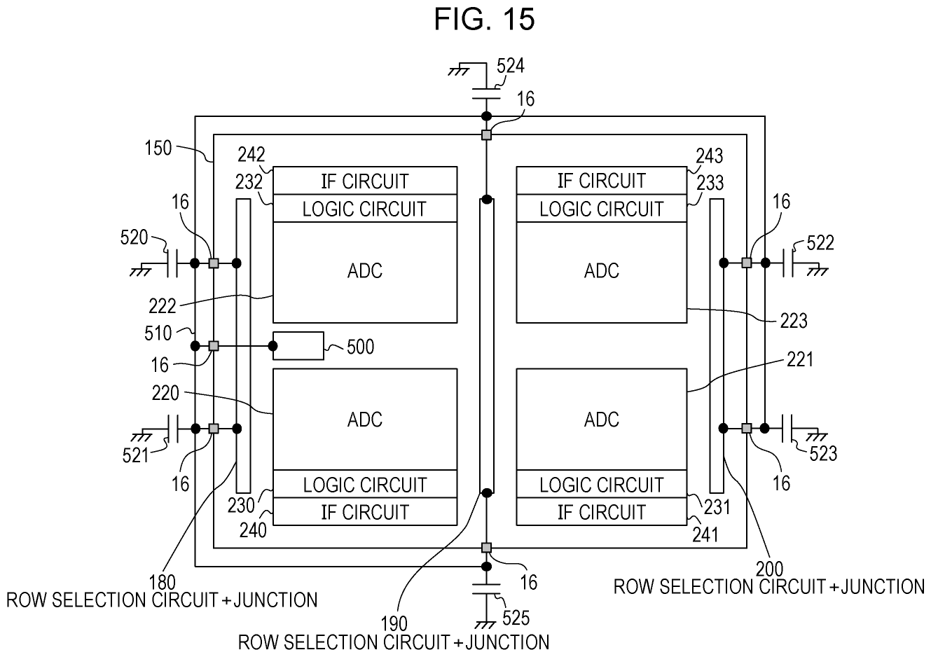

FIG. 15 is a schematic illustration of a solid-state image pickup device according to the present embodiment. In the description below, only the differences from FIG. 2 according to the first embodiment are described. According to the present embodiment, three row selection circuits 180, 190, and 200 are provided. In addition, voltage is supplied to each of the row selection circuits 180, 190, and 200 at two locations via the wiring portion 510 outside of the solid-state image pickup device 1000.

This configuration enables a decrease in the impedance of the voltage supply paths to the row selection circuits 180, 190, and 200. In addition, by supplying the voltage to each of the row selection circuits 180, 190, and 200 at two locations, the influence of the wiring impedance inside of each of the row selection circuits 180, 190, and 200 can be reduced.

### Fourth Embodiment

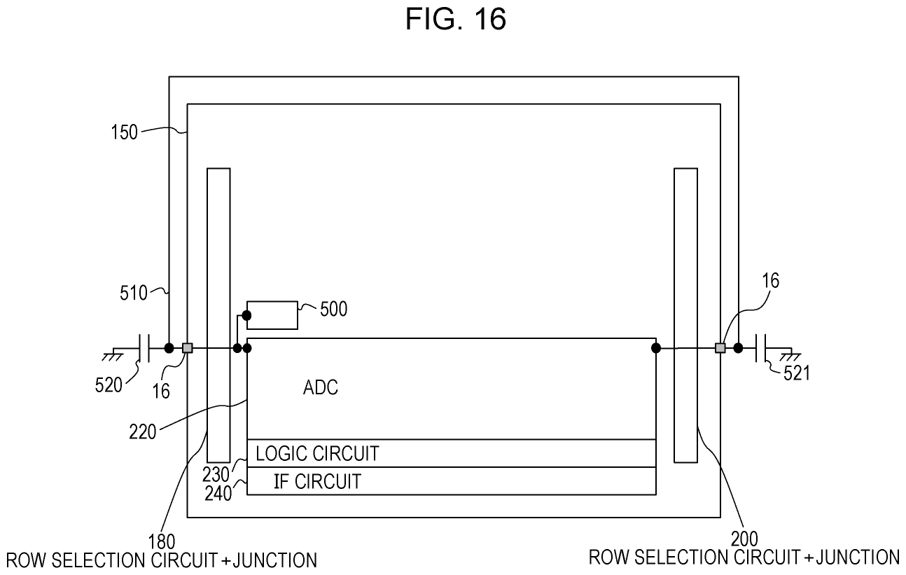

While the first to third embodiments have been described above with reference to the case of supplying voltage from the voltage generation circuit 500 to the row selection circuit as an example, supplying of the voltage is not limited thereto. For example, as illustrated in FIG. 16, voltage can be supplied to the ADC 220. In this case, each of a plurality of functional elements that have the same function and that receive the supplied first voltage is at least one of the current source 40, the comparator 60, the first memory 70, and the second memory 80 included in the circuit CRT of the ADC 220 illustrated in FIG. 4.

The functional element may be a combination of a plurality of circuit blocks. For example, in the case of ground potential, the current source 40, the comparator 60, the first memory 70, and the second memory 80 may be supplied with ground potential from a common conductor line. In this case, each of the plurality of functional elements that have the same function and that receive the ground potential (the first voltage) can be the entire circuit CRT.

In FIG. 16, voltage is supplied from the voltage generation circuit 500 to the plurality of ADCs 220 at two locations, and the voltage at one of the two locations is supplied via the wiring portion 510 outside of the solid-state image pickup device 1000. In this case, the one of the two locations where the voltage is supplied is, for example, between the pad portion 16 located in one end portion of the solid-state image pickup device 1000 and the ADC 220 located in the center of the plurality of ADCs 220. A portion at the one of the two locations where the voltage is supplied can be a via portion connecting conductor lines in a plurality of layers for supplying the voltage to the ADC 220.

More specifically, the portion can be a via portion that is located within the range of about 500 columns of ADCs 220 as viewed from the pad portion 16 located in the one end portion of the solid-state image pickup device 1000 and that connects the conductor lines in a plurality of layers for supplying the voltage to the ADCs 220. Similarly, the other of the two locations where the voltage is supplied is, for example, between the pad portion 16 located in the other end portion of the solid-state image pickup device 1000 and the ADC 220 located at the center of the plurality of ADCs 220. A portion at the other of the two locations where the voltage is supplied can be a via portion connecting conductor lines in a plurality of layers for supplying the voltage to the ADC 220.

More specifically, the portion can be a via portion that is located within the range of about 500 columns of ADCs 220 as viewed from the pad portion 16 located in the other end portion of the solid-state image pickup device 1000 and that connects the conductor lines in a plurality of layers for supplying voltage to the ADCs 220. It is desirable that among the plurality of ADCs 220, the ADCs at both ends be selected and that the conductor lines extend toward the center from both the ends to each of the ADCs.

An example of the voltage to be supplied is the bias voltage of the current source 40 and the comparator 60 in FIG. 4. This configuration can reduce voltage fluctuations of the voltage supplied to the ADC 220, thus preventing a decrease in the operation accuracy of the ADC 220.

As illustrated in FIG. 17, the voltage generation circuit 500 can be used to supply voltage to the pixel 10. In this case, for example, the voltage generation circuit 500 can supply the ground voltage to be supplied to the GND node 450 of the pixel 10 and the power supply voltage to be supplied to the power supply node 460 via the wiring portion 510. In this case, each of the plurality of functional elements that have the same function and that receive the supplied first voltage is one of the plurality of pixels 10.

In FIG. 17, the power supply voltage is supplied from the voltage generation circuit 500 to the pixel substrate 110 via an inter-substrate junction 700. The power supply voltage is also supplied from the right side of the pixel substrate 110 via the wiring portion 510 outside of the solid-state image pickup device 1000 and an inter-substrate junction 710. This configuration can reduce voltage fluctuations of the voltage supplied to the pixel 10 and, thus, degradation of the operation accuracy of the pixel 10 can be reduced.

The embodiments of the solid-state image pickup device are not limited to those described above. For example, the number of signal lines 30 is not limited to one per pixel column, but may be two or more. The stacking configuration may be a three-layer stacking configuration. The pixel 10 is not limited to that illustrated in FIG. 5. For example, when a plurality of signal lines 30 are provided, a plurality of selection transistors 440 may be provided. A floating diffusion 420 may be shared by a plurality of photodiodes 400.

While the above embodiments have been primarily described with reference to solid-state image pickup devices, the embodiments can also be applied to a storage device with a memory (a DRAM, SRAM, or the like). This is because one aspect of the technique of the present disclosure is related to the structure including a plurality of functional elements that have the same function and a voltage generation circuit, and voltage generated by the voltage generation circuit is supplied to the plurality of functional elements via a conductor line outside of the structure. The plurality of functional elements can be a plurality of memory cells in the storage device or can be a plurality of drive elements included in a circuit unit that controls writing to or reading from the plurality of memory cells.

### Fifth Embodiment

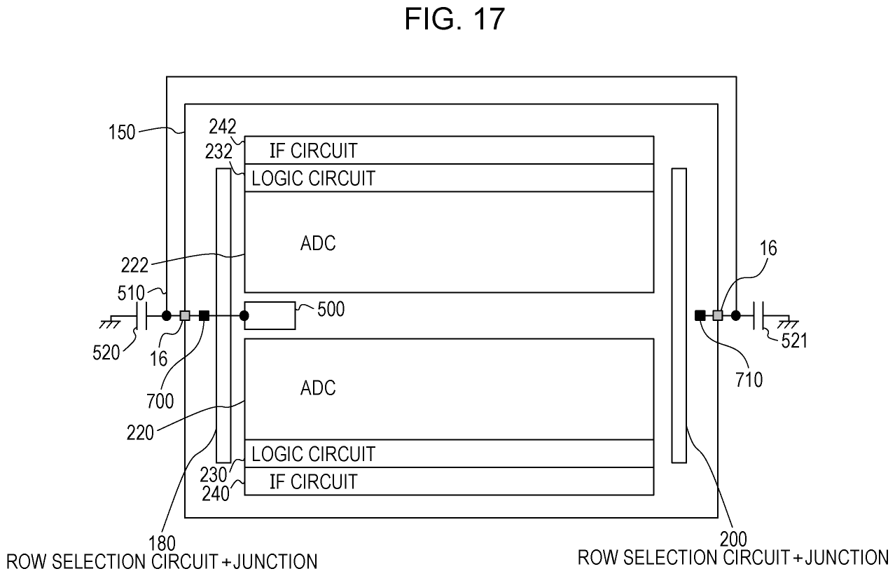

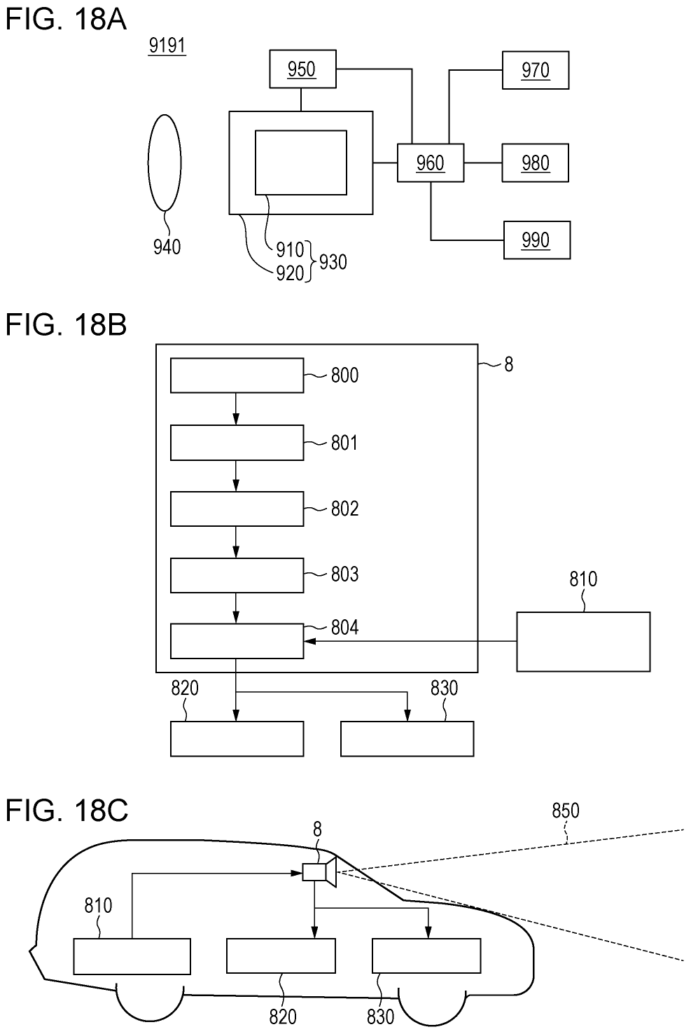

The fifth embodiment can be applied to any of the first to fourth embodiments. FIG. 18A is a schematic illustration of equipment 9191 including a semiconductor apparatus 930 according to the present embodiment. The image pickup device according to each of the above-described embodiments can be used as the semiconductor apparatus 930. The equipment 9191 including the semiconductor apparatus 930 is described in detail below.

As described above, the semiconductor apparatus 930 can include, in addition to a semiconductor device 910, a package 920 that contains the semiconductor device 910. The package 920 can include a base member having the semiconductor device 910 fixed thereto and a lid member, such as a glass member, facing the semiconductor device 910. The package 920 can further include a joint member, such as a bonding wire and a bump, that connects a terminal provided on the base member to a terminal provided on the semiconductor device 910.

The equipment 9191 can include at least one of an optical device 940, a control device 950, a processing device 960, a display device 970, a storage device 980, and a mechanical device 990. The optical device 940 corresponds to the semiconductor apparatus 930. The optical device 940 is, for example, a lens, a shutter, and a mirror. The control device 950 controls the semiconductor apparatus 930. The control device 950 is a semiconductor apparatus, such as an application specific integrated circuit (ASIC).

The processing device 960 processes a signal output from the semiconductor apparatus 930. The processing device 960 is a semiconductor apparatus, such as a CPU or an ASIC, for constituting an AFE (analog front end) or a DFE (digital front end). The display device 970 is an EL display device or a liquid crystal display device that displays information (an image) obtained by the semiconductor apparatus 930. The storage device 980 is a magnetic device or a semiconductor device that stores information (an image) obtained by the semiconductor apparatus 930. The storage device 980 is a volatile memory, such as an SRAM or a DRAM, or a nonvolatile memory, such as a flash memory or a hard disk drive.

The mechanical device 990 includes a moving or driving unit, such as a motor or an engine. In the equipment 9191, a signal output from the semiconductor apparatus 930 is displayed on the display device 970 or is transmitted to the outside by a communication device (not illustrated) included in the equipment 9191. For this purpose, it is desirable that the equipment 9191 further include the storage device 980 and the processing device 960 in addition to a storage circuit and an arithmetic operation circuit of the semiconductor apparatus 930. The mechanical device 990 may be controlled on the basis of a signal output from the semiconductor apparatus 930.

The equipment 9191 is also suitable for electronic equipment, such as an information terminal having an image pickup function (e.g., a smartphone or a wearable device) or a camera (e.g., an interchangeable lens camera, a compact camera, a camcorder, or a surveillance camera). The mechanical device 990 in a camera can drive components of the optical device 940 for zooming, focusing, and a shutter operation. Alternatively, the mechanical device 990 in a camera can move the semiconductor apparatus 930 for a vibration-proofing operation.

The equipment 9191 can be transport equipment, such as a vehicle, a ship, or an air vehicle. The mechanical device 990 in the transport equipment can be used as a moving apparatus. The equipment 9191 serving as a transport equipment is suitable for transporting the semiconductor apparatus 930 or for assisting and/or automating driving (maneuvering) by using the image pickup function. The processing device 960 for assisting and/or automating driving (maneuvering) can perform processing to operate the mechanical device 990 serving as a moving apparatus on the basis of information obtained by the semiconductor apparatus 930. Alternatively, the equipment 9191 may be medical equipment, such as an endoscope, measuring equipment, such as a ranging sensor, analytical equipment, such as an electronic microscope, office equipment, such as a copying machine, or industrial equipment, such as a robot.

According to the embodiments described above, excellent pixel characteristics can be obtained. Accordingly, the value of the semiconductor apparatus can be enhanced. The term “enhancing the value” as used herein refers to at least one of adding a function, improving performance, improving the characteristics, improving the reliability, improving the manufacturing yield, reducing the environmental impact, reducing the cost, reducing the size, and reducing the weight.

Therefore, if the semiconductor apparatus 930 according to the present embodiment is used in the equipment 9191, the value of the equipment can also be enhanced. For example, the semiconductor apparatus 930 can be mounted in transport equipment to obtain excellent performance in capturing the image of the outside of the transport equipment or measuring the external environment. Therefore, in manufacturing and selling transport equipment, deciding to mount the semiconductor apparatus according to the present embodiment in the transport equipment is advantageous in enhancing the performance of the transport equipment itself. In particular, the semiconductor apparatus 930 is suitable for transport equipment that uses information obtained by the semiconductor apparatus for drive assist and/or automated driving of the transport equipment.

A photoelectric conversion system and a mobile object according to the present embodiment are described below with reference to FIGS. 18A to 18C.

FIG. 18A illustrates an example of a photoelectric conversion system related to an on-vehicle camera. A photoelectric conversion system 8 includes a photoelectric conversion device 800. The photoelectric conversion device 800 is the image pickup device according to any of the above-described embodiments.

The photoelectric conversion system 8 further includes an image processing unit 801 that performs image processing on a plurality of image data acquired by the photoelectric conversion device 800 and a parallax acquisition unit 802 that calculates the parallax (the phase difference between parallax images) from the plurality of image data acquired by the photoelectric conversion system 8. The photoelectric conversion system 8 further includes a distance acquisition unit 803 that calculates the distance to a physical object on the basis of the calculated parallax and a collision determination unit 804 that determines whether there is a possibility of collision on the basis of the calculated distance.

The parallax acquisition unit 802 and the distance acquisition unit 803 are an example of a distance information acquisition unit for acquiring information about the distance to a physical object. That is, the distance information is information regarding the parallax, defocus amount, distance to the physical object, and the like. The collision determination unit 804 may use any one of the pieces of distance information to determine the possibility of collision.

The distance information acquisition unit may be implemented by dedicated designed hardware or by a software module. Alternatively, the distance information acquisition unit may be implemented by a field programmable gate array (FPGA), an ASIC, or a combination thereof.

The photoelectric conversion system 8 is connected to a vehicle information acquisition device 810 and can acquire vehicle information, such as the vehicle speed, yaw rate, and steering angle. The photoelectric conversion system 8 is connected to a control ECU 820 which is a control device that outputs a control signal for generating a braking force to the vehicle on the basis of the determination result of the collision determination unit 804. The photoelectric conversion system 8 is also connected to an alarm device 830 that emits an alarm to a driver on the basis of the determination result of the collision determination unit 804.

For example, if the collision determination unit 804 determines that the collision probability is high, the control ECU 820 performs vehicle control to avoid collisions or reduce damage by braking, releasing the accelerator pedal, or reducing the engine output. The alarm device 830 emits an alarm to a user by, for example, sounding the alarm, displaying alarm information on a screen of a car navigation system, or vibrating a seat belt or steering wheel.

According to the present embodiment, the photoelectric conversion system 8 captures the image of the surroundings of the vehicle, for example, the front view or rear view of the vehicle.

FIG. 18C illustrates the photoelectric conversion system that captures the image of the front view of the vehicle (an image sensing area 850). The vehicle information acquisition device 810 sends an instruction to the photoelectric conversion system 8 or the photoelectric conversion device 800. Such a configuration can improve the accuracy of distance measurement more.

While an example of performing control so as not to collide with another vehicle has been described, the configuration can also be applied to control of self-driving vehicles to follow another vehicle or control of self-driving vehicles to keep the lane. Furthermore, the photoelectric conversion system can be applied not only to a vehicle, but also to a mobile object (a moving apparatus), such as a boat, an aircraft, or an industrial robot. Still furthermore, the photoelectric conversion system can be applied not only to a mobile object but also to equipment that uses object recognition over a wide area, such as an intelligent transportation system (ITS).

The embodiments described above can be modified as necessary without departing from the technical scope and spirit of the present disclosure. The disclosure herein includes not only the matters described in the present specification but also all matters that can be understood from the present specification and the drawings attached to the present specification.

In addition, the present disclosure contains a complementary set of a concept described herein. That is, for example, if the present specification contains a description of the case where “A is greater than B”, it can be said that the present specification discloses the case where “A is not greater than B” even if a description of the case where “A is not greater than B” is omitted. This is because it is presupposed that when the case where “A is greater than B” is described, the case where “A is not greater than B” is took into consideration.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-066474 filed Apr. 14, 2023, which is hereby incorporated by reference herein in its entirety.

What is claimed is:

1. A semiconductor apparatus comprising:
a structure including a pixel array having a plurality of pixels arranged in a plurality of rows and a plurality of columns, a circuit unit configured to scan the plurality of pixels or process signals output from the plurality of pixels, and a voltage generation circuit configured to generate a first voltage; and
a wiring portion provided outside of the structure,
wherein the first voltage is supplied from the voltage generation circuit to the circuit unit via the wiring portion.

2. The semiconductor apparatus according to claim 1, wherein the structure includes a connecting portion to connect to the wiring portion.

3. The semiconductor apparatus according to claim 2, wherein the structure includes an insulating film, a recess is formed inside of the insulating film, and the connecting portion is a pad electrode provided inside of the recess.

4. The semiconductor apparatus according to claim 3, wherein the pad electrode is connected to a conductor line containing a material primarily consisting of gold.

5. The semiconductor apparatus according to claim 3, wherein the pad electrode contains a material primarily consisting of aluminum.

6. The semiconductor apparatus according to claim 3, wherein a row selection circuit is provided in a plurality of row selection circuits,
wherein the circuit unit includes the plurality of row selection circuits, each configured to select, from among the plurality of pixels, pixels from which signals are to be read out on a row basis, and
wherein the pad electrode is provided corresponding to each of the plurality of row selection circuits.

7. The semiconductor apparatus according to claim 2, wherein the connecting portion is a solder ball.

8. The semiconductor apparatus according to claim 1, wherein the circuit unit includes a row selection circuit configured to select, from among the plurality of pixels, pixels from which signals are to be read out on a row basis.

9. The semiconductor apparatus according to claim 8, wherein the row selection circuit is a plurality of row selection circuits, and the circuit unit includes the plurality of row selection circuits.

10. The semiconductor apparatus according to claim 1, wherein the circuit unit is a plurality of circuit units, and the voltage generation circuit is configured to supply the first voltage to the plurality of circuit units.

11. The semiconductor apparatus according to claim 1,
wherein the circuit unit includes a plurality of drive circuits configured to scan the plurality of pixels and output signals to control the plurality of pixels, and
wherein the voltage generation circuit is configured to supply the first voltage to at least one of the drive circuits.

12. The semiconductor apparatus according to claim 1, further comprising a capacitor element including a plurality of terminals,
wherein, when voltage is supplied, the first voltage is supplied to one of the plurality of terminals, and a second voltage that differs from the first voltage is supplied to another one of the plurality of terminals, and
wherein the wiring portion is electrically connected to the one of the plurality of terminals.

13. The semiconductor apparatus according to claim 1, wherein the wiring portion has a portion that overlaps the semiconductor apparatus in plan view as viewed from a normal direction of a light receiving surface of the semiconductor apparatus.

14. The semiconductor apparatus according to claim 1, wherein the structure includes a layered structure in which a pixel substrate having the pixel array and a circuit substrate having the circuit unit are stacked.

15. The semiconductor apparatus according to claim 14, wherein the voltage generation circuit is provided in the circuit substrate.

16. The semiconductor apparatus according to claim 14, wherein the circuit unit is provided in the pixel substrate, and the voltage generation circuit is provided in the pixel substrate.

17. The semiconductor apparatus according to claim 14, wherein the circuit unit is provided in the circuit substrate, and the voltage generation circuit is provided in the circuit substrate.

18. The semiconductor apparatus according to claim 1, wherein each of the plurality of pixels include a photoelectric conversion portion configured to generate signal charge, an amplifier transistor including a first gate to which the generated signal charge is input, and a reset transistor including a second gate and configured to reset the first gate, and
wherein the first voltage is used to generate a signal to be input to the second gate.

19. The semiconductor apparatus according to claim 1, wherein each of the plurality of pixels include a photoelectric conversion portion configured to generate signal charge, an amplifier transistor including a first gate to which the generated signal charge is input, and a transistor including a second gate and connected to the first gate to change a capacitance value connected to the first gate, and
wherein the first voltage is used to generate a signal to be input to the second gate.

20. The semiconductor apparatus according to claim 1, wherein the first voltage is input to an analog-to-digital (AD) converter configured to process a signal from a pixel of the plurality of pixels.

21. The semiconductor apparatus according to claim 1, wherein the first voltage is input as a power supply voltage of a pixel of the plurality of pixels.

22. A semiconductor apparatus comprising:
a structure including a pixel array having a plurality of pixels arranged in a plurality of rows and a plurality of columns, a circuit unit configured to scan the plurality of pixels, and a voltage generation circuit configured to generate a voltage; and
a wiring portion provided outside of the structure,
wherein the voltage is supplied from the voltage generation circuit to the circuit unit via the wiring portion.

23. A semiconductor apparatus comprising:
a structure including a pixel array having a plurality of pixels arranged in a plurality of rows and a plurality of columns, a circuit unit configured to process signals output from the plurality of pixels, and a voltage generation circuit configured to generate a voltage; and
a wiring portion provided outside of the structure,
wherein the voltage is supplied from the voltage generation circuit to the circuit unit via the wiring portion.

24. A semiconductor apparatus comprising:
a structure including a pixel array having a plurality of pixels arranged in a plurality of rows and a plurality of columns, and a voltage generation circuit configured to generate a first voltage; and
a wiring portion provided outside of the structure,
wherein the first voltage is supplied from the voltage generation circuit to the pixel array via the wiring portion.

25. A semiconductor apparatus comprising:
a structure including a plurality of functional elements having the same function and a voltage generation circuit configured to generate a first voltage; and
a wiring portion provided outside of the structure,
wherein the first voltage is supplied from the voltage generation circuit to the plurality of functional elements via the wiring portion.

26. Equipment comprising:
the semiconductor apparatus according to claim 1; and
at least one of the following:
an optical device corresponding to the semiconductor apparatus,
a control device configured to control the semiconductor apparatus,
a processing device configured to process a signal output from the semiconductor apparatus,
a display device configured to display information acquired by the semiconductor apparatus,
a storage device configured to store information acquired by the semiconductor apparatus, or
a mechanical device configured to operate based on information acquired by the semiconductor apparatus.
